(19) United States
(12) Patent Application Publication
(10) Pub. No.: US 2009/0319878 A1
(43) Pub. Date: Dec. 24, 2009

(54) CHECK CODE GENERATING APPARATUS, METHOD OF GENERATING CHECK CODE, AND COMMUNICATION APPARATUS

(75) Inventor: Satoshi KABURAKI, Tokyo (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: KABUSHIKI KAISHA TOSHIBA, Tokyo (JP)

(21) Appl. No.: 12/481,238

(22) Filed: Jun. 9, 2009

(30) Foreign Application Priority Data
Jun. 24, 2008 (JP) 2008-164544

(51) Int. Cl. H03M 13/09; G06F 11/10

(52) U.S. Cl. 714/807; 714/E11.032

(57) ABSTRACT

A check code generating apparatus generates a first check code that is a check code concerning exclusive OR of first data and second data obtained by rewriting a part of the first data and calculates exclusive OR of the first check code and a second check code that is a check code attached to the first data.

### CROSS-REFERENCE TO RELATED APPLICATIONS

This application is based upon and claims the benefit of priority from the prior Japanese Patent Application No. 2008-164544, filed on Jun. 24, 2008; the entire contents of which are incorporated herein by reference.

### BACKGROUND OF THE INVENTION

1. Field of the Invention

The present invention relates to a check code generating apparatus, a method of generating a check code, and a communication apparatus.

2. Description of the Related Art

As a code for detecting errors in a frame and a packet for communication, there is, for example, a cyclic redundancy check code (CRC). For example, IEEE802.11 specifies that a 32-bit CRC called frame check sequence (FCS) is attached to the end of an IEEE802.11 radio frame. When frames and packets are transmitted, a part of frames and packets transmitted earlier may be rewritten and retransmitted or transferred. For example, in radio communication, it is assumed that, after transmitting a frame, a transmission side cannot receive an acknowledge (Ack) frame transmitted from a reception side, which receives the frame, as an affirmative response because of some reason (e.g., the transmitted frame does not reach the reception side or the Ack frame transmitted from the reception side does not reach the transmission side). In this case, the frame is retransmitted from the transmission side. The transmission side transmits a retransmission frame in which a retry field indicating retransmission is rewritten. In the technology in the past, although the retransmission frame has completely the same frame body as that of the frame transmitted earlier except that one bit in the part of the retry field is different, a CRC is entirely calculated again. For example, Japanese Patent Application Laid-Open No. 11-68581 discloses a technology for, in rewriting an asynchronous transfer mode (ATM) header, calculating a CRC in a rewritten section with hardware and calculating a new CRC using a calculation result.

### BRIEF SUMMARY OF THE INVENTION

A check code generating apparatus according to an embodiment of the present invention comprises: a check-code calculating unit that generates a first check code that is a check code concerning exclusive OR of first data and second data obtained by rewriting a part of the first data; and an exclusive-OR calculating unit that calculates an exclusive OR of the first check code generated by the check-code calculating unit and a second check code that is a check code attached to the first data.

A method of generating a check code according to an embodiment of the present invention comprises: generating a first check code that is a check code concerning exclusive OR of first data and second data obtained by rewriting a part of the first data; and calculating an exclusive OR of the first check code and a second check code that is a check code attached to the first data.

A communication apparatus according to an embodiment of the present invention comprises: a check-code calculating unit that generates a first check code that is a check code concerning exclusive OR of first data and second data obtained by rewriting a part of the first data; and an exclusive-OR calculating unit that calculates an exclusive OR of the first check code generated by the check-code calculating unit and a second check code that is a check code attached to the first data.

### BRIEF DESCRIPTION OF THE DRAWINGS

FIG. 1 is a diagram of a block configuration of a radio communication apparatus for generating a CRC with a method of generating a check code according to a first embodiment of the present invention;

FIG. 2 is a diagram for explaining a frame and a CRC;

FIG. 3 is a diagram for explaining a CRC as a first check code;

FIG. 4 is a diagram for explaining a procedure for generating a CRC attached to a retransmission frame;

FIG. 5 is a diagram for explaining a linear code generated by a method of generating a check code according to a second embodiment of the present invention;

FIG. 6 is a diagram for explaining a procedure for generating a CRC according to the second embodiment;

FIG. 7 is a diagram for explaining the structure of a table for associating values of a TTL field of a reception packet and a CRC with each other;

FIG. 8 is a diagram for explaining a procedure for generating a CRC of a transfer packet from a reception packet using the table;

FIG. 9 is a diagram for explaining the structure of a table referred to in a method of generating a check code according to a third embodiment of the present invention;

FIG. 10 is a diagram for explaining a procedure for generating a CRC of a transfer packet from a reception packet using the table; and

FIG. 11 is a diagram of a block configuration of a radio communication apparatus for generating a CRC with a method of generating a check code according to a fourth embodiment of the present invention.

### DETAILED DESCRIPTION OF THE INVENTION

Exemplary embodiments of a check code generating apparatus, a method of generating check code, and a communication apparatus according to the present invention will be explained below in detail with reference to the accompanying drawings.

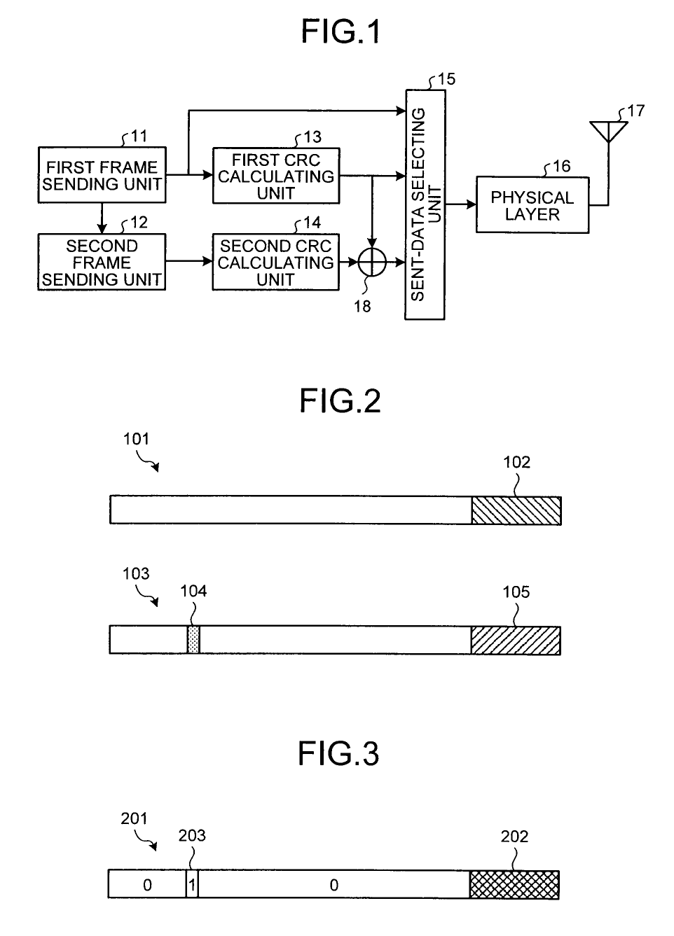

FIG. 1 is a diagram of a block configuration of a radio communication apparatus for generating a CRC with a method of generating a check code according to a first embodiment of the present invention. In the method of generating a check code according to this embodiment, a first check code is generated in advance by arithmetic operation and, when second data is generated, a check code is generated by calculating exclusive OR of the first check code and a second check code.

A first frame sending unit 11 (a first data sending unit) is a unit that sends a frame 101 (first data) shown in FIG. 2. The first frame sending unit 11 performs MAC processing and the like. The frame 101 is an IEEE802.11 radio frame. A 32-bit CRC 102 is attached to the end of the frame 101. A first CRC calculating unit 13 calculates the CRC 102 attached to the frame 101.

A sent-data selecting unit 15 selects data to be input to a physical layer 16. The sent-data selecting unit 15 selects output from the first frame sending unit 11 and sends the output to the physical layer 16 while a body of the frame 101 is output from the first frame sending unit 11. When the first frame sending unit 11 finishes the output, the sent-data selecting unit 15 selects output from the first CRC calculating unit 13 and sends the output to the physical layer 16.

Besides being directly sent from the first frame sending unit 11 to the sent-data selecting unit 15, the frame 101 can be sent from the first frame sending unit 11 to the sent-data selecting unit 15 through the first RC calculating unit 13. In this case, the first CRC calculating unit 13 causes the frame 101 to pass through the first CRC calculating unit 13 while the first frame sending unit 11 outputs the frame 101. When the first frame sending unit 11 finishes the output, the first CRC calculating unit 13 sends the CRC 102 to the sent-data selecting unit 15. Data is converted into an analog signal in the physical layer 16 and transmitted to a not-shown reception side from an antenna 17 via a radio wave.

A retry field 104 is a flag present in a twelfth bit from the top of an MAC header in a radio LAN frame. The retry field 104 is set to “0” in the frame 101 transmitted in the first time. A retransmission frame 103 has the same frame body as that of the frame 101 except that the retry field 104 is rewritten from “0” to “1”. When the frame 101 is first data, the retransmission frame 103 is second data obtained by rewriting a part of the first data. The CRC 102 attached to the frame 101 and a CRC 105 attached to the retransmission frame 103 are check codes including linear codes.

After the frame 101 is transmitted, when a transmission side cannot receive an Ack frame because of some reason, the first frame sending unit 11 sends the retransmission frame 103 obtained by changing the retry field 104 to “1” from the frame 101 sent in the first time. While a body of the retransmission frame 103 is output from the first frame sending unit 11, the sent-data selecting unit 15 selects output from the first frame sending unit 11 and sends the output to the physical layer 16.

A second frame sending unit 12 (a second data sending unit) sends a frame 201 shown in FIG. 3. The frame 201 has the same length as the frame 101 and has a frame body in which only a section 203 corresponding to the retry field 104 is “1” and a section except the section 203 is “0”. A second CRC calculating unit 14 functions as a check-code calculating unit that calculates a CRC 202 attached to the frame 201. The CRC 202 is a check code (a first check code) concerning the frame 201 as exclusive OR of the frame 101 as the first data and the retransmission frame 103 as the second data.

An arithmetic circuit 18 functions as an exclusive-OR calculating unit that calculates exclusive OR of the CRC 202 generated by the second CRC calculating unit 14 and the CRC 102 (the second check code) generated by the first CRC calculating unit 13. The second CRC calculating unit 14 and the arithmetic circuit 18 function as a check code generating apparatus that generates a CRC 105 attached to the retransmission frame 103.

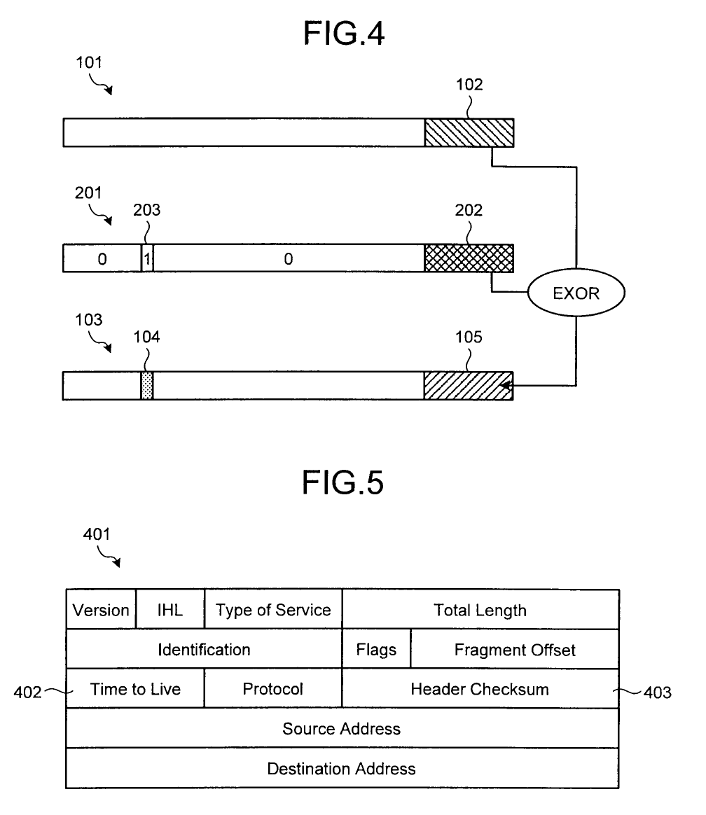

FIG. 4 is a diagram for explaining a procedure for generating the CRC 105 attached to the retransmission frame 103. The CRC 202 explained with reference to FIG. 3 is generated by calculation in the second CRC calculating unit 14 and stored. When the retransmission frame 103 is generated, the arithmetic circuit 18 calculates exclusive OR (represented as “EXOR” in the figure) of the CRC 202 and the CRC 102 attached to the frame 101. The arithmetic circuit 18 generates the CRC 105 attached to the retransmission frame 103 by calculating exclusive OR of the CRC 202 and the CRC 102.

When the first frame sending unit 11 finishes the output of the body of the retransmission frame 103, the sent-data selecting unit 15 selects exclusive OR output by the arithmetic circuit 18. In this way, the CRC 105 attached to the retransmission frame 103 is input to the physical layer 16. According to the present invention, when a part of a frame having a check code including a linear code is changed, it is possible to generate a check code concerning a new frame with simple calculation compared with generation of a check code by a normal method.

In this embodiment, besides storing only the CRC 202 of the frame 201 and using the CRC 202 for calculation, the entire frame 201 including the CRC 202 can be stored. In this case, the retransmission frame 103 can be generated by calculating exclusive OR of the entire frame 201 and the entire frame 101 to be transmitted in the first time.

The second frame sending unit 12 can generate the frame 201 with relatively easy calculation based on the frame 101 generated by the first sending unit 11. Therefore, the second frame sending unit 12 can be configured simpler than the first frame sending unit 11. Besides being configured to include the first frame sending unit 11 and the second frame sending unit 12 independent from each other, the radio communication apparatus can be configured to cause one component to function as the first frame sending unit 11 and the second frame sending unit 12. The radio communication apparatus can also attach an error detection correction code including a linear code to the physical layer 16. The present invention can be applied to generation of an error detection correction code in the physical layer 16.

The present invention is not limited to the application to the IEEE802.11 radio frame explained in this embodiment. The present invention is widely applicable to data such as a frame and a packet having a check code including a linear code. The present invention is applied not only to retransmission or transfer of the data such as a frame and a packet and but also to both the transmission and the transfer. The present invention is not only used for generation of a CRC but also used for generation of a linear code except the CRC, for example, a Reed Solomon (RS) code.

A method of generating a check code according to this embodiment can be both a method of using processing by a hardware configuration and a method of using processing by a software configuration. When the processing by the hardware configuration is used, for example, a multiplexer can be used as the sent-data selecting unit 15. In the case of the processing by the software configuration, an increase in a computational amount often causes a problem. Therefore, the method of generating a check code according to this embodiment is useful.

FIG. 5 is a diagram for explaining a linear code generated by a method of generating a check code according to a second embodiment of the present invention. The structure of an Internet protocol (IP) header 401 is shown in FIG. 5. A time to live (TTL) field 402 of the IP header 401 indicates the number of routers, through which a packet can pass, as time to live of the packet. A value of the TTL field 402 is reduced by one every time the routers transfer the packet to another node. A packet, a value of the TTL field 402 of which is “1”, is not transferred by the routers and discarded in the router. A header checksum 403 is a checksum of the entire packet.

Besides, the IP header 401 includes fields of a version, Internet header length (IHL), a type of service, total length, identification, flags, fragment offset, a protocol, a source address, and a destination address. Detailed explanation of the fields except the TTL field 402 and the header checksum 403 of the IP header 401 is omitted.

The header checksum 403 of the IP header 401 generally used is not a linear code. However, the Internet Engineering Task Force (IETF) refers to, in RFC791, use of a CRC as a linear code instead of a checksum (see, for example, http://tools.ietf.org/html/rfc791). In the explanation of this embodiment, it is assumed that a CRC is used instead of a checksum.

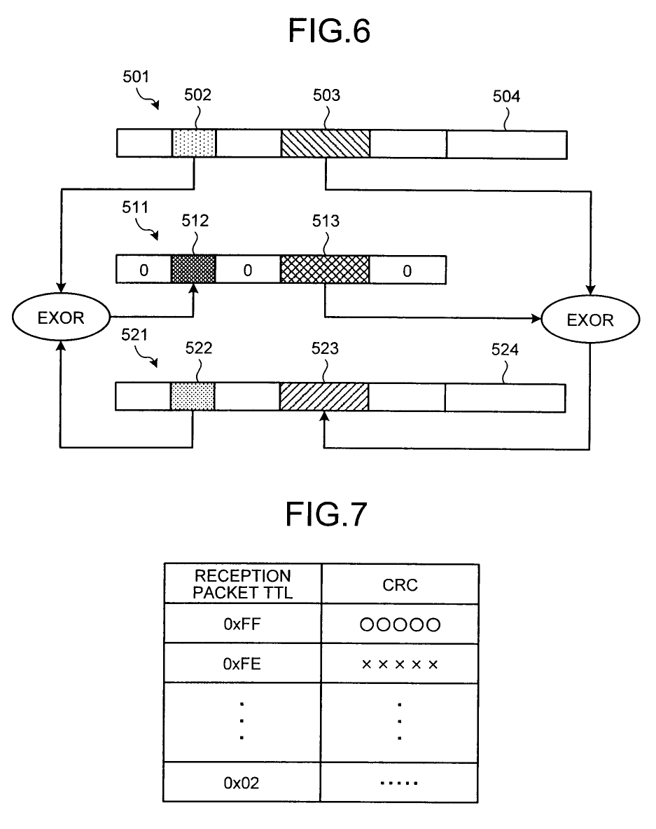

FIG. 6 is a diagram for explaining a procedure for generating a CRC 523 according to this embodiment. A router that receives a reception packet 501 reduces a value of a TTL field 502 by one and transfers the reception packet 501 to the next node. A CRC 503 attached to the reception packet 501 and a CRC 523 attached to a transfer packet 521 are check codes including linear codes. A section 504 except an IP header of the reception packet 501 and a section 524 except an IP header of the transfer packet 521 are, for example, TCP frames.

A TTL field 522 of the transfer packet 521 is updated to a value obtained by reducing a value of the TTL field 502 of the reception packet by one. The CRC 523 attached to the transfer packet 521 needs to be generated anew according to the update of the value of the TTL field 522. In this embodiment, before the CRC 523 of the transfer packet 521 is generated, a CRC 513 concerning a packet 511 shown in FIG. 6 is generated in advance. The packet 511 is a packet including only a section equivalent to an IP header. The packet 511 includes a TTL difference 512 and the CRC 513 as a check code concerning an IP header, all sections of which except the TTL difference 512 are “0”. The TTL difference 512 is exclusive OR of values of the TTL field 502 and the TTL field 522 that are different from each other in an IP header (first data) of the reception packet 501 and an IP header (second data) of the transfer packet 521. The CRC 513 is a check code (a first check code) concerning the packet 511 that is exclusive OR of the IP header of the reception packet 501 and the IP header of the transfer packet 521.

FIG. 7 is a diagram for explaining the structure of a table for associating values of the TTL field 502 of the reception packet 501 and the CRC 513. A value of the TTL field 502 is, for example, an 8-bit value. In the first embodiment, the CRC 105 attached to the retransmission frame 103 is uniquely decided for the frame 101 (see FIG. 4). On the other hand, in this embodiment, because the TTL difference 512 takes a plurality of values according to the values of the TTL field 502, the CRC 513 concerning the packet 511 including the TTL difference 512 is not uniquely decided.

When the table is created, concerning values excluding “1” and “0” among values that the TTL field 502 can take, the TTL difference 512 as exclusive OR of a value of the TTL field 502 and a value obtained by reducing one from the value is calculated. The CRC 513 is calculated for an IP header, sections of which except the TTL difference 512 are “0”, by using the TTL difference 512. When values of the TTL field 502 are “1” and “0”, because the transfer packet 521 is not generated, the values can be excluded from the table. In this embodiment, the table for associating the values of the TTL field 502 of the reception packet 501 and the generated CRC 513 is stored. The CRC 523 of the transfer packet 521 is generated by using the CRC 513 obtained with reference to the table.

The table stores 254 values 0xFF to 0x02 excluding 0x01 and 0x00 among 8 bits, which the TTL field 502 can take, and the CRC 513 in association with each other. The notation of “0x??” represents hexadecimal number. It is possible to easily create the table by calculating in advance the CRC check code 513 for values excluding “1” and “0” among the values that the TTL field 502 can take. A communication apparatus can store the table in advance from, for example, a point of manufacturing of the communication apparatus. By performing calculation during initial setting when a power supply for the communication apparatus is turned on, the table can be created every time the power supply for the communication apparatus is turned on.

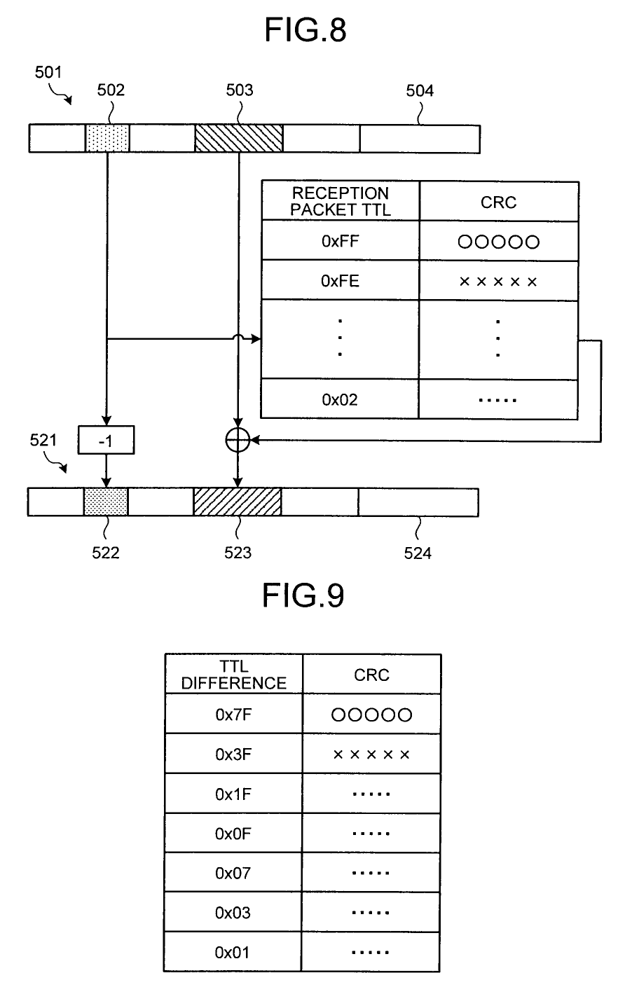

FIG. 8 is a diagram for explaining a procedure for generating the CRC 523 of the transfer packet 521 from the reception packet 501 using the table explained with reference to FIG. 7. In the method of generating a check code according to this embodiment, the CRC 523 is generated by using processing by software. First, the TTL field 502 of the reception packet 501 is referred to and a value obtained by reducing one from a value of the TTL field 502 referred to is calculated and written in the TTL field 522 of the transfer packet 521. When the value of the TTL field 502 is “1”, processing explained below is not performed and the reception packet 501 is discarded in a router.

The CRC 513 corresponding to the value of the TTL field 502 is calculated by referring to the table explained with reference to FIG. 7 and is stored in the router. The CRC 523 of the transfer packet 521 is generated by calculating exclusive OR of the stored CRC 513 (the first check code) and the CRC 503 (the second check code) of the reception packet 501. A value same as that of the reception packet 501 is written in sections except the TTL field 522 and the CRC 523 of the transfer packet 521. In this way, the transfer packet 521 is generated.

Besides being generated in a memory area different from that of the reception packet 501, the transfer packet 521 can be generated by directly rewriting, on a memory area, the TTL field 502 and the CRC 513 of the reception packet 501. In this case, copying on the memory concerning sections except the TTL field 502 and the CRC 503 of the reception packet 501, i.e., sections that do not need to be written in transfer can be omitted.

As explained above, in this embodiment, the table is referred to when the transfer packet 521 including the second data is generated. Consequently, when a part of a packet having a check code including a linear code is changed, it is possible to generate a check code for a new packet with simple calculation compared with generation of a check code by the normal method.

The processing for calculating a value obtained by reducing the value of the TTL field 502 by one does not always have to be performed before the processing for generating the CRC 523 of the transfer packet 521. These kinds of processing can be performed in any order. The table referred to when the CRC 523 is generated does not always have to include the value of the TTL field 502 of the reception packet 501. The table can include, for example, a value of the TTL field 522 obtained by reducing the value of the TTL field 502 of the reception packet 501 by one. This embodiment is not only applied to the IP packet that uses the CRC instead of the checksum and can be widely applied to data such as a frame and a packet having a check code including a linear code.

FIG. 9 is a diagram for explaining the structure of a table referred to in a method of generating a check code according to a third embodiment of the present invention. In this embodiment, a table that stores values of the TTL difference 512 (see FIG. 6) of the packet 511 and the CRC 513 in association with each other is used. The TTL difference 512 is exclusive OR of values of the TTL field 502 and the TTL field 522 that are different from each other in the first data and the second data.

When the value of the TTL field 502 is an 8-bit value, the TTL difference 512 as exclusive OR of the 8-bit value and a value obtained by reducing one from the value is any one of seven values 0x7F to 0x01 as shown in FIG. 9. The table used in this embodiment includes only seven entries. Therefore, this embodiment has an advantage that the size of the table can be reduced. In this embodiment, as in the second embodiment, a communication apparatus can store the table in advance or, by performing calculation during initial setting when a power supply for the communication apparatus is turned on, the table can be created every time the power supply for the communication apparatus is turned on.

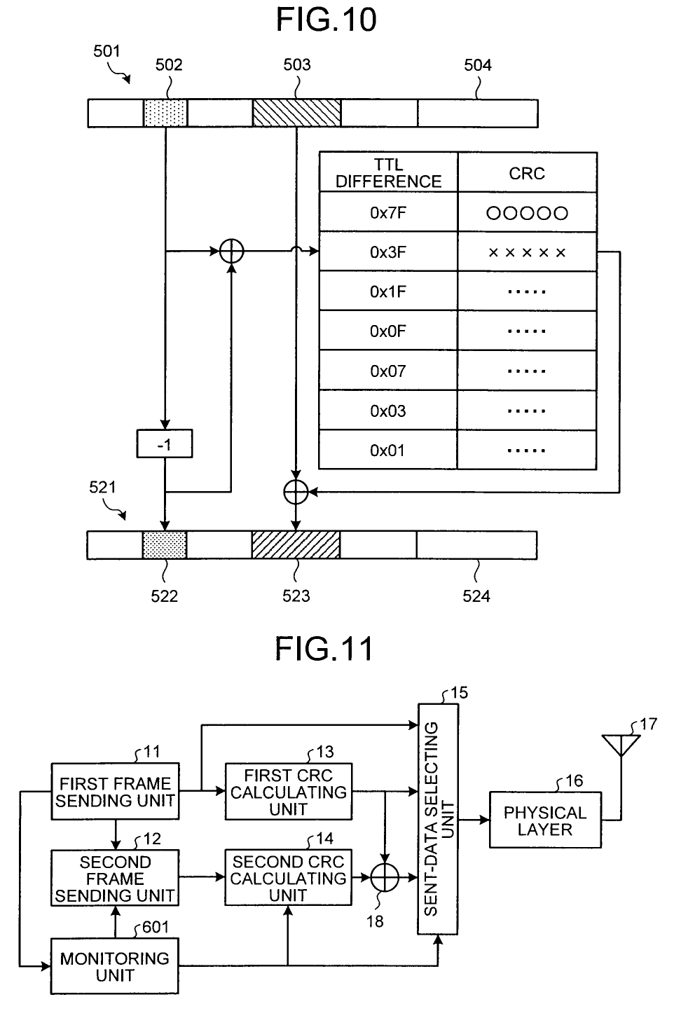

FIG. 10 is a diagram for explaining a procedure for generating the CRC 523 of the transfer packet 521 from the reception packet 501 using the table explained with reference to FIG. 9. First, the TTL field 502 of the reception packet 501 is referred to and a value obtained by reducing one from a value of the TTL field 502 referred to is calculated and written in the TTL field 522 of the transfer packet 521. When the value of the TTL field 502 is “1”, processing explained below is not performed and the reception packet 501 is discarded in a router.

Subsequently, the TTL difference 512 is generated by calculating exclusive OR of the value of the TTL field 502 of the reception packet 501 and the value obtained by reducing one from the value. After the TTL difference 512 is generated, the CRC 513 corresponding to a value of the TTL difference 512 is calculated by referring to the table explained with reference to FIG. 9. The CRC 523 of the transfer packet 521 is generated by calculating exclusive OR of the CRC 513 (the first check code) calculated by referring to the table and the CRC 503 (the second check code) of the reception packet 501.

A value same as that of the reception packet 501 is written in sections except the TTL field 522 and the CRC 523 of the transfer packet 521. In this way, the transfer packet 521 is generated. In this embodiment, as in the second embodiment, besides being generated in a memory area different from that of the reception packet 501, the transfer packet 521 can be generated by directly rewriting the TTL field 502 and the CRC 513 of the reception packet 501 on a memory area.

The TTL difference 512 is generated by calculation at any time. Besides, a table that stores values of the TTL field 502 of the reception packet 501 or values of the TTL field 522 of the transfer packet 521 and the TTL difference 512 in association with each other is separately prepared. The TTL difference 512 can be calculated by referring to the table.

FIG. 11 is a diagram of a block configuration of a radio communication apparatus for generating a CRC with a method of generating a check code according to a fourth embodiment of the present invention. In the explanation of this embodiment, it is assumed that the CRC 105 (see FIG. 2) explained in the first embodiment is generated. Components same as those in the first embodiment are denoted by the same reference numerals and signs and redundant explanation of the components is omitted. In the first embodiment, the CRC 202 (see FIG. 3) of the frame 201 is generated in advance. On the other hand, in the fourth embodiment, when the frame 101 as the first data is sent, the CRC 202 (the first check code) of the frame 201 is generated in parallel to the generation of the CRC 102 of the frame 101.

The sending of the frame 201 by the second frame sending unit 12 and the calculation of the CRC 202 by the second CRC calculating unit 14 are performed in parallel to the sending of the frame 101 by the first frame sending unit 11 and the calculation of the CRC 102 by the first CRC calculating unit 13. The CRC check code 202 calculated by the second CRC calculating unit 14 is not used in transmitting the frame 101 in the first time and stored in the second CRC calculating unit 14. When a transmission side receives an Ack frame from a reception side, the CRC 202 stored in the second CRC calculating unit 14 is erased because the CRC 202 is unnecessary.

After the frame 101 is transmitted, when the transmission side cannot receive the Ack frame because of some reason, the first frame sending unit 11 sends the retransmission frame 103 obtained by changing the retry field 104 to “1” from the frame 101 sent in the first time. While a body of the retransmission frame 103 is output from the first frame sending unit 11, the sent-data selecting unit 15 selects output from the first frame sending unit 11 and sends the output to the physical layer 16. While the output from the first frame sending unit 11 is selected by the sent-data selecting unit 15, the calculation by the first CRC calculating unit 13 and the second CRC calculating unit 14 is stopped.

In this embodiment, when the retransmission frame 103 as the second data is sent, the arithmetic circuit 18 calculates exclusive OR of the CRC 202 (the first check code) and the CRC 102 (the second check code). When first frame sending unit 11 finishes the output of the body of the retransmission frame 103, the sent-data selecting unit 15 selects exclusive OR output by the arithmetic circuit 18. In this way, the CRC 105 attached to the retransmission frame 103 is input to the physical layer 16.

As explained above, the CRC 202 is generated in parallel to the sending of the frame 101 by the first frame sending unit 11 and the generation of the CRC 102 by the first CRC calculating unit 13. Consequently, even when the length of the frame 101 is not fixed, it is possible to generate the CRC 202 corresponding to the frame 101 every time the frame 101 is sent. Because the CRC 202 is generated in parallel to the generation of the CRC 102, it is possible to omit calculation of a CRC at the time of transmission of the retransmission frame 103 without calculating the CRC 202 in advance.

The monitoring unit 601 monitors a communication state at the time when the radio communication apparatus transmits a frame via a radio wave. The monitoring unit 601 counts the number of times of retransmission of the frame and determines a radio wave state from the number of times of retransmission. For example, the monitoring unit 601 sets a threshold of the number of times of retransmission in a fixed period or a fixed number of times of transmission in advance. The monitoring unit 601 determines whether the radio wave state is satisfactory according to whether the number of times of retransmission is equal to or smaller than the threshold determined from statistics in the past. The monitoring unit 601 controls, according to the communication state, the operation of the second frame sending unit 12 and the second CRC calculating unit 14. When the number of times of retransmission is equal to or smaller than the threshold and the monitoring unit 601 determines that the radio wave state is satisfactory, the monitoring unit 601 stops the operation of the second frame sending unit 12 and the second CRC calculating unit 14. In transmitting the retransmission frame 103, the radio communication apparatus generates the CRC 202 according to the calculation by the first CRC calculating unit 13 during the retransmission. The sent-data selecting unit 15 sequentially selects, according to the determination of the monitoring unit 601 that the radio wave state is satisfactory, output from the first frame sending unit 11 and output from the first CRC calculating unit 13.

When the monitoring unit 601 determines that the number of times of retransmission is larger than the predetermined threshold and the radio wave state is unsatisfactory, the monitoring unit 601 actuates the second frame sending unit 12 and the second CRC calculating unit 14. The sent-data selecting unit 15 sequentially selects, according to the determination of the monitoring unit 601 that the radio wave state is unsatisfactory, output from the first frame sending unit 11, output from the first CRC calculating unit 13, and exclusive OR output by the arithmetic circuit 18. This makes it possible to stop the calculation of the second frame sending unit 12 and the second CRC calculating unit 14 when the radio wave state is satisfactory and a frequency of retransmission is low and reduce calculation and a memory capacity that are wasted because the retransmission frame 103 is not transmitted. The determination of a communication state by the monitoring unit 601 is not limited to the method of determining the communication state using a threshold of the number of times of retransmission determined from statistics in the past. Any determination method may be used.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A check code generating apparatus that generates a check code including a liner code, the check code generating apparatus comprising:
a check-code calculating unit that generates a first check code that is a check code concerning exclusive OR of first data and second data obtained by rewriting a part of the first data; and
an exclusive-OR calculating unit that calculates an exclusive OR of the first check code generated by the check-code calculating unit and a second check code that is a check code attached to the first data.

2. The check code generating apparatus according to claim 1, wherein the first check code is generated by the check-code calculating unit in advance and stored.

3. The check code generating apparatus according to claim 1, wherein
the check-code calculating unit generates the first check code according to calculation performed when the first data is sent, and
the exclusive-OR calculating unit calculates exclusive OR of the first check code and the second check code when the second data is sent.

4. The check code generating apparatus according to claim 3, wherein operation of the check-code calculating unit is controlled according to a communication state at the time when data is transmitted.

5. A method of generating a check code including a linear code, comprising:
generating a first check code that is a check code concerning exclusive OR of first data and second data obtained by rewriting a part of the first data; and
calculating an exclusive OR of the first check code and a second check code that is a check code attached to the first data.

6. The method of generating a check code according to claim 5, wherein the first check code is generated by the calculation in advance and stored.

7. The method of generating a check code according to claim 5, further comprising:
storing a table including the first check code; and
referring to the table in generating the second data.

8. The method of generating a check code according to claim 7, wherein the table stores exclusive OR of sections different from each other of the first data and the second data and the first check code in association with each other.

9. The method of generating a check code according to claim 5, further comprising:
generating the first check code according to calculation performed when the first data is sent; and
calculating exclusive OR of the first check code and the second check code when the second data is sent.

10. The method of generating a check code according to claim 9, further comprising controlling generation of the first check code according to a communication state at the time when data is transmitted.

11. A communication apparatus that generates a check code including a linear code and sends data attached with the check code, the communication apparatus comprising:
a check-code calculating unit that generates a first check code that is a check code concerning exclusive OR of first data and second data obtained by rewriting a part of the first data; and
an exclusive-OR calculating unit that calculates an exclusive OR of the first check code generated by the check-code calculating unit and a second check code that is a check code attached to the first data.

12. The communication apparatus according to claim 11, wherein the first check code generated by the check-code calculating unit in advance is stored.

13. The communication apparatus according to claim 11, further comprising:
a first data sending unit that sends the first data and the second data; and
a second data sending unit that sends data that is exclusive OR of the first data and the second data.

14. The communication apparatus according to claim 11, further comprising:
a first check-code calculating unit that calculates a check code attached to the first data; and
a second check-code calculating unit as the check-code calculating unit.

15. The communication apparatus according to claim 11, further comprising:
a first data sending unit that sends the first data and the second data;
a second data sending unit that sends data that is exclusive OR of the first data and the second data;
a first check-code calculating unit that calculates a check code attached to the first data;
a second check-code calculating unit as the check-code calculating unit; and
a sent-data selecting unit that selects data input to a physical layer, wherein
the sent-data selecting unit selects output from the first check-code calculating unit when the first data sending unit finishes output of a body of the first data and selects output from the exclusive-OR calculating unit when the first data sending unit finishes output of a body of the second data.

16. The communication apparatus according to claim 11, wherein
the communication apparatus stores a table including the first check code generated by the check-code calculating unit, and
the exclusive-OR calculating unit refers to the table in generating the second data.

17. The communication apparatus according to claim 16, wherein the table stores exclusive OR of sections different from each other of the first data and the second data and the first check code in association with each other.

18. The communication apparatus according to claim 11, wherein
the check-code calculating unit generates the first check code when the first data is sent, and
the exclusive-OR calculating unit calculates exclusive OR of the first check code and the second check code when the second data is sent.

19. The communication apparatus according to claim 18, further comprising:
a first data sending unit that sends the first data and the second data;
a second data sending unit that sends data that is exclusive OR of the first data and the second data; and
a monitoring unit that monitors a communication state at the time when the data is transmitted, wherein
the monitoring unit controls operation of the check-code calculating unit and the second data sending unit according to the communication state.

20. The communication apparatus according to claim 19, wherein the monitoring unit determines the communication state according to the number of times of retransmission of the data.
